(19) United States
(12) Patent Application Publication
(10) Pub. No.: US 2026/0079212 A1
(43) Pub. Date: Mar. 19, 2026

(54) DEVICE AND METHOD FOR ADJUSTING FULL CHARGE CAPACITY INFORMATION ABOUT BATTERY

(71) Applicant: Samsung Electronics Co., Ltd., Suwon-si (KR)

(72) Inventors: Jaesung LEE, Suwon-si (KR); Seungho LEE, Suwon-si (KR); Hyekyung JEON, Suwon-si (KR)

(21) Appl. No.: 19/400,093

(22) Filed: Nov. 25, 2025

Related U.S. Application Data
(63) Continuation of application No. PCT/KR2024/012037, filed on Aug. 13, 2024.

(30) Foreign Application Priority Data
Oct. 6, 2023 (KR) 10-2023-0133138
Aug. 25, 2023 (KR) 10-2023-0111839

(51) Int. Cl. G01R 31/388; G01R 31/36; G01R 31/389

(52) U.S. Cl. CPC G01R 31/388; G01R 31/3646; G01R 31/389

(57) ABSTRACT

An electronic device is provided. The electronic device includes a battery, a load, a communication module configured to establish communication with an external device, and memory, including one or more storage media, storing instructions and a threshold resistance value, and at least one processor, comprising a processing circuit, communicatively coupled to the battery, the load, the communication circuit, and the memory, wherein the instructions, when executed by the at least one processor individually or collectively, cause the electronic device to supply a current to the load based on the battery being fully charged, determine the value of the internal resistance of the battery based on the current and a voltage, measured after the current is supplied to the load of the battery, adjust full charge capacity information about the battery based on a comparison between the determined value of the internal resistance and a threshold resistance value, and share, with the external device, state of charge (SOC) information about the battery determined based on the adjusted full charge capacity information.

### CROSS-REFERENCE TO RELATED APPLICATIONS

This application is a continuation application, claiming priority under 35 U.S.C. § 365(c), of an International application No. PCT/KR2024/012037, filed on August 13, 2024, which is based on and claims the benefit of a Korean patent application number 10-2023-0111839, filed on August 25, 2023, in the Korean Intellectual Property Office, and of a Korean patent application number 10-2023-0133138, filed on October 6, 2023, in the Korean Intellectual Property Office, the disclosure of each of which is incorporated by reference herein in its entirety.

### BACKGROUND

### 1. Field

The disclosure relates to a technology of adjusting full charge capacity information of a battery.

### 2. Description of Related Art

With the recent development of digital technologies, various types of electronic devices, such as mobile communication terminals, smartphones, tablet personal computers (PCs), electronic notebooks, personal digital assistants (PDAs), wearable devices, digital cameras, PCs, and the like, are being widely used.

Electronic devices often include batteries with electrical properties, such as high energy density and high applicability across product categories. Batteries may alternate between charging and discharging, and electronic devices need to efficiently control these charging and discharging processes to maintain optimal operating conditions and performance of the batteries.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a technology of adjusting full charge capacity information of a battery.

Additional aspects will be set forth in part in the description which follows and, in part, will be apparent from the description, or may be learned by practice of the presented embodiments.

In accordance with an aspect of the disclosure, an electronic device is provided. The electronic device includes a battery having an internal resistance, a load electrically connected to the battery, a communication circuit configured to establish communication with an external device, memory, including one or more storage media, storing instructions and a threshold resistance value, and at least one processor, including a processing circuit, communicatively coupled to the battery, the load, the communication circuit, and the memory, wherein the instructions, when executed by the at least one processor individually or collectively, cause the electronic device to supply a current to the load based on the battery being fully charged, determine a resistance value of the internal resistance based on a magnitude of a voltage of the battery and a magnitude of a current measured while supplying the current to the load, adjust full charge capacity information of the battery based on a comparison between the determined resistance value of the internal resistance and the threshold resistance value, and share state of charge (SOC) information of the battery determined based on the adjusted full charge capacity information with the external device.

In accordance with another aspect of the disclosure, an electronic device is provided. The electronic device includes a communication circuit configured to establish communication with an external device including a battery, a display, memory, including one or more storage media, storing instructions, at least one processor, including a processing circuit, communicatively coupled to the communication circuit, the display, and the memory, wherein the instructions, when executed by the at least one processor individually or collectively, cause the electronic device to, based on adjusting full charge capacity information of the battery, obtain, from the external device, SOC information of the battery determined using the adjusted full charge capacity information, and display a screen based on the obtained SOC information.

In accordance with another aspect of the disclosure, a method performed by an electronic device is provided. The method includes supplying a current to a load that is electrically connected to a battery, based on the battery being fully charged, determining a resistance value of an internal resistance of the battery based on a magnitude of a voltage of the battery and a magnitude of a current measured while supplying the current to the load, adjusting full charge capacity information of the battery based on a comparison between the determined resistance value of the internal resistance and a threshold resistance value, and sharing SOC information of the battery determined based on the adjusted full charge capacity information with an external device.

In accordance with another aspect of the disclosure, one or more non-transitory computer-readable storage media storing one or more computer programs comprising computer-executable instructions that, when executed by one or more processors of an electronic device individually or collectively, cause the electronic device to perform operations are provided. The operations include supplying a current to a load that is electrically connected to a battery, based on the battery being fully charged, determining a resistance value of an internal resistance of the battery based on a magnitude of a voltage of the battery and a magnitude of a current measured while supplying the current to the load, adjusting full charge capacity information of the battery based on a comparison between the determined resistance value of the internal resistance and a threshold resistance value, and sharing state of charge (SOC) information of the battery determined based on the adjusted full charge capacity information with an external device.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 is a block diagram illustrating a power management module and a battery according to an embodiment of the disclosure;

FIG. 3 is a diagram schematically illustrating a configuration related to battery control in an electronic device according to an embodiment of the disclosure;

FIG. 4 is a flowchart illustrating a method performed by an electronic device according to an embodiment of the disclosure;

FIG. 5 is a graph illustrating changes in a charging current during a charging operation of a battery according to an embodiment of the disclosure;

FIG. 6 is a flowchart illustrating changing a threshold resistance value by a first electronic device according to an embodiment of the disclosure;

FIG. 7 is a diagram illustrating displaying a screen based on obtained information by a second electronic device that has obtained the information about a battery of a first electronic device from the first electronic device according to an embodiment of the disclosure;

FIG. 8 is a flowchart illustrating a method of controlling a charging operation of a battery by a first electronic device according to an embodiment of the disclosure; and

FIG. 9 is a flowchart illustrating a method of determining current magnitude information about a current supplied to a load by a first electronic device according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth^{TM} chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

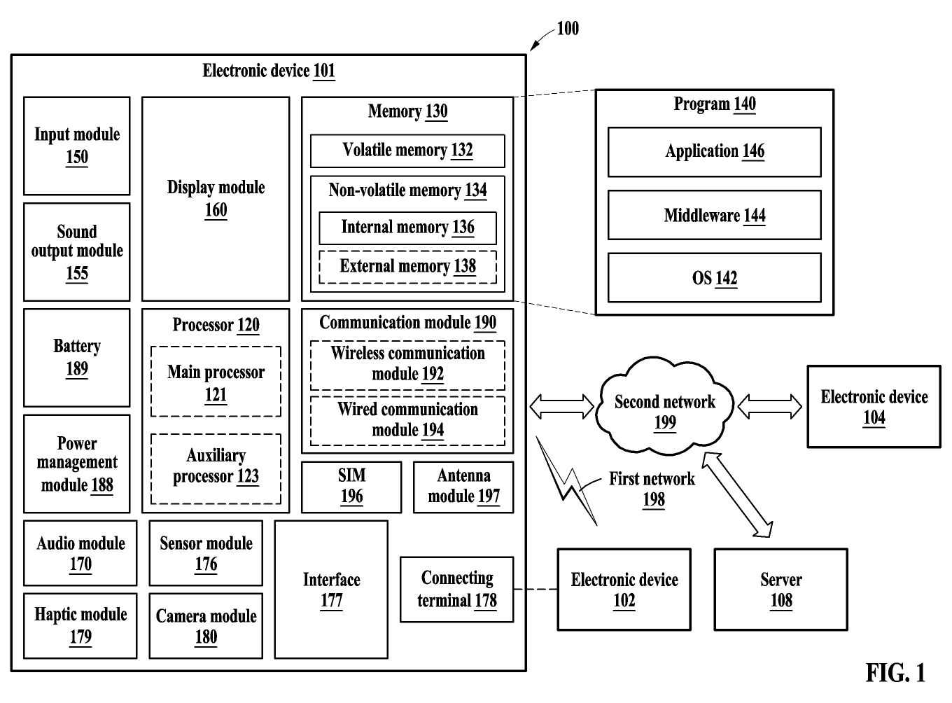

FIG. 1 is a block diagram illustrating an electronic device in a network environment according to an embodiment of the disclosure.

Referring to FIG. 1, an electronic device 101 in a network environment 100 may communicate with an external electronic device 102 via a first network 198 (e.g., a short-range wireless communication network), or at least one of an external electronic device 104 or a server 108 via a second network 199 (e.g., a long-range wireless communication network). According to an embodiment of the disclosure, the electronic device 101 may communicate with the external electronic device 104 via the server 108. According to an embodiment of the disclosure, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments of the disclosure, at least one of the components (e.g., the connecting terminal 178) may be omitted from the electronic device 101, or one or more other components may be added to the electronic device 101. In some embodiments of the disclosure, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment of the disclosure, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment of the disclosure, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., a sleep) state, or together with the main processor 121 while the main processor 121 is in an active state (e.g., executing an application). According to an embodiment of the disclosure, the auxiliary processor 123 (e.g., an ISP or a CP) may be implemented as part of another component (e.g., the camera module 180 or the communication module 190) functionally related to the auxiliary processor 123. According to an embodiment of the disclosure, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment of the disclosure, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment of the disclosure, the display module 160 may include a touch sensor adapted to detect a touch, or a pressure sensor adapted to measure the intensity of force incurred by the touch.

The audio module 170 may convert a sound into an electrical signal and vice versa. According to an embodiment of the disclosure, the audio module 170 may obtain the sound via the input module 150, or output the sound via an external electronic device (e.g., the external electronic device 102) (e.g., a speaker or headphone) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment of the disclosure, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the external electronic device 102) directly (e.g., wiredly) or wirelessly. According to an embodiment of the disclosure, the interface 177 may include, for example, a high definition multimedia interface (HDMI), a universal serial bus (USB) interface, a secure digital (SD) card interface, or an audio interface.

The connecting terminal 178 may include a connector via which the electronic device 101 may be physically connected with the external electronic device (e.g., the external electronic device 102). According to an embodiment of the disclosure, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment of the disclosure, the haptic module 179 may include, for example, a motor, a piezoelectric element, or an electric stimulator.

The camera module 180 may capture a still image or moving images. According to an embodiment of the disclosure, the camera module 180 may include one or more lenses, image sensors, ISPs, or flashes.

The power management module 188 may manage power supplied to the electronic device 101. According to one embodiment of the disclosure, the power management module 188 may be implemented as at least part of, for example, a power management integrated circuit (PMIC).

The battery 189 may supply power to at least one component of the electronic device 101. According to an embodiment of the disclosure, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the external electronic device 102, the external electronic device 104, or the server 108) and performing communication via the established communication channel. The communication module 190 may include one or more CPs that are operable independently from the processor 120 (e.g., the AP) and support a direct (e.g., wired) communication or a wireless communication. According to an embodiment of the disclosure, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth^{TM}, wireless-fidelity (Wi-Fi) direct, or infrared data association (IrDA)) or the second network 199 (e.g., a long-range communication network, such as a legacy cellular network, a fifth-generation (5G) network, a next-generation communication network, the Internet, or a computer network (e.g., LAN or wide area network (WAN)). These various types of communication modules may be implemented as a single component (e.g., a single chip), or may be implemented as multiple components (e.g., multiple chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network, after a fourth-generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the external electronic device 104), or a network system (e.g., the second network 199). According to an embodiment of the disclosure, the wireless communication module 192 may support a peak data rate (e.g., 20 Gbps or more) for implementing eMBB, loss coverage (e.g., 164 dB or less) for implementing mMTC, or user plane (U-plane) latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment of the disclosure, the antenna module 197 may include an antenna including a radiating element including a conductive material or a conductive pattern formed in or on a substrate (e.g., a printed circuit board (PCB)). According to an embodiment of the disclosure, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment of the disclosure, another component (e.g., a radio frequency integrated circuit (RFIC)) other than the radiating element may be additionally formed as part of the antenna module 197.

According to various embodiments of the disclosure, the antenna module 197 may form a mmWave antenna module. According to an embodiment of the disclosure, the mmWave antenna module may include a PCB, a RFIC disposed on a first surface (e.g., the bottom surface) of the PCB, or adjacent to the first surface and capable of supporting a designated high-frequency band (e.g., the mmWave band), and a plurality of antennas (e.g., array antennas) disposed on a second surface (e.g., the top or a side surface) of the PCB, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment of the disclosure, commands or data may be transmitted or received between the electronic device 101 and the external electronic device 104 via the server 108 coupled with the second network 199. Each of the external electronic devices 102 or 104 may be a device of a same type as, or a different type, from the electronic device 101. According to an embodiment of the disclosure, all or some of operations to be executed at the electronic device 101 may be executed at one or more of the external electronic devices 102 or 104, or the server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, cloud computing, distributed computing, mobile edge computing (MEC), or client-server computing technology may be used, for example. The electronic device 101 may provide ultra low-latency services using, e.g., distributed computing or mobile edge computing. In another embodiment of the disclosure, the external electronic device 104 may include an Internet-of-things (IoT) device. The server 108 may be an intelligent server using machine learning and/or a neural network. According to an embodiment of the disclosure, the external electronic device 104 or the server 108 may be included in the second network 199. The electronic device 101 may be applied to intelligent services (e.g., a smart home, a smart city, a smart car, or healthcare) based on 5G communication technology or IoT-related technology.

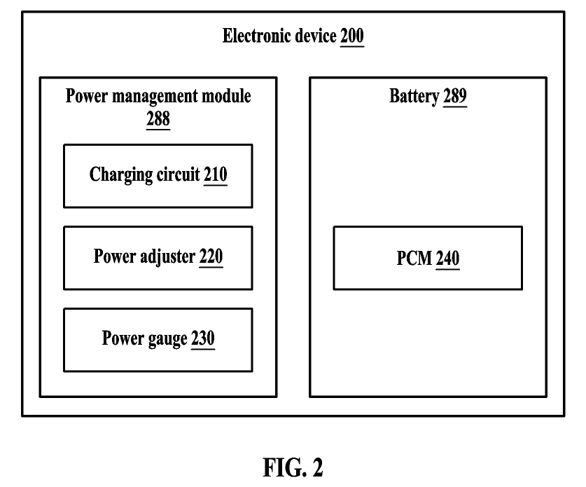

FIG. 2 is a block diagram illustrating a power management module and a battery, according to an embodiment of the disclosure.

Referring to FIG. 2, an electronic device 200 according to an embodiment (e.g., the electronic device 101 of FIG. 1) may include a power management module 288 (e.g., the power management module 188 of FIG. 1) and a battery 289 (e.g., the battery 189 of FIG. 1).

The power management module 288 may include a charging circuit 210, a power adjuster 220, or a power gauge 230. The charging circuit 210 may charge the battery 289 using power supplied from an external power source outside the electronic device 200. According to an embodiment of the disclosure, the charging circuit 210 may select a charging scheme (e.g., normal charging or quick charging) based at least in part on a type of an external power source (e.g., a power outlet and USB or wireless charging), a magnitude of power suppliable from the external power source (e.g., about 20 W or more), or an attribute of the battery 289. The charging circuit 210 may charge the battery 289 using the selected charging scheme. The external power source may be connected with the electronic device 200, for example, directly via a connecting terminal (e.g., the connecting terminal 178 of FIG. 1) or wirelessly via an antenna module (e.g., the antenna module 197 of FIG. 1).

The power adjuster 220 may generate a plurality of powers having different voltage levels or different current levels by adjusting a voltage level or a current level of the power supplied from the external power source or the battery 289. The power adjuster 220 may adjust the voltage level or the current level of the power supplied from the external power source or the battery 289 into a different voltage level or current level appropriate for each of some of the components included in the electronic device 200. According to an embodiment of the disclosure, the power adjuster 220 may be implemented in a form of a low drop out (LDO) regulator or a switching regulator. The power gauge 230 may measure use state information about the battery 289 (e.g., the capacity, the number of charging or discharging times, the voltage, or the temperature of the battery 289).

The power management module 288 may determine, using, for example, the charging circuit 210, the power adjuster 220, or the power gauge 230, state of charge (SOC) information (e.g., lifespan, over voltage, low voltage, over current, over charge, over discharge, overheat, short, or swelling) related to the charging of the battery 189 based at least in part on the measured use state information about the battery 289. The power management module 288 may determine whether the state of the battery 289 is normal or abnormal based at least in part on the determined SOC information. If the state of the battery 289 is determined to be abnormal, the power management module 288 may adjust the charging of the battery 289 (e.g., reduce the charging current and/or the charging voltage, or stop the charging). According to an embodiment of the disclosure, at least some of functions of the power management module 288 may be performed by a control device (e.g., the processor 120 of FIG. 1) other than the power management module 288.

According to an embodiment of the disclosure, the battery 289 may include a protection circuit module (PCM) 240. The PCM 240 may perform one or more of various functions (e.g., a pre-cutoff function) to prevent performance deterioration of, or damage to, the battery 289. The PCM 240, additionally or alternatively, may be configured as at least part of a battery management system (BMS) capable of performing various functions including cell balancing, measurement of battery capacity, count of the number of charging or discharging times, measurement of temperature, or measurement of voltage.

According to an embodiment of the disclosure, at least part of the SOC information or use state information regarding the battery 289 may be measured using a corresponding sensor (e.g., a temperature sensor) of a sensor module, the power gauge 230, or the power management module 288. According to an embodiment of the disclosure, the corresponding sensor (e.g., a temperature sensor) of sensor modules (e.g., the sensor module 176 of FIG. 1) may be included as part of the PCM 240 or may be disposed near the battery 289 as a separate device.

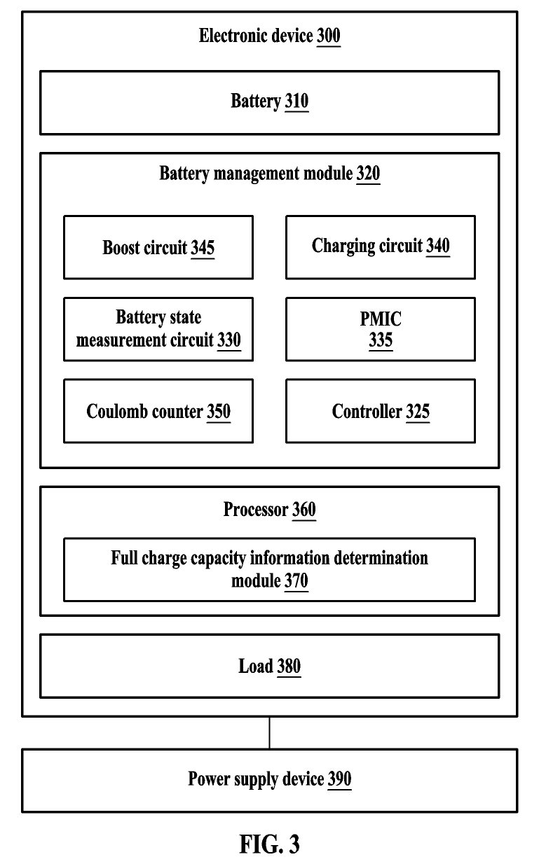

FIG. 3 is a diagram schematically illustrating a configuration related to battery control in an electronic device according to an embodiment of the disclosure.

Referring to FIG. 3, according to various embodiments of the disclosure, an electronic device 300 (e.g., the electronic device 101 of FIG. 1) may include, for example, a processor 360 (e.g., an AP; the processor 120 of FIG. 1), a battery management module 320 (e.g., the power management module 188 of FIG. 1 and the power management module 288 of FIG. 2), a battery 310 (e.g., the battery 189 of FIG. 1 and the battery 289 of FIG. 2), and a load 380. According to various embodiments of the disclosure, the electronic device 300 may be connected by wire or wirelessly to a power supply device 390 for supplying power from outside the electronic device 300. In FIG. 3, the power supply device 390 is not a component included in the electronic device 300 and may be illustrated for better understanding of the disclosure.

The electronic device 300 may include the battery 310 that is rechargeable, and the battery 310 may be charged by directly receiving output power of the power supply device 390 that supplies power. According to various embodiments of the disclosure, the battery 310 of the electronic device 300 may be charged through a separate charging device (e.g., a battery charging dock or cradle).

The power supply device 390 may include, for example, a travel adapter (TA) or a power supply. In various embodiments of the disclosure, the power supply device 390 may be integrated with the charging device as an integral device or may be implemented as a separate device (e.g., a charger) and connected to the charging device. Hereinafter, the power supply device 390 is described as including the role of the charging device.

The power supply device 390 may be a device that supplies power (e.g., a voltage and a current) to the electronic device 300 to charge the battery 310 of the electronic device 300. The power supply device 390 may provide a voltage or a current of various levels. According to various embodiments of the disclosure, the power supply device 390 may output a reference voltage or a voltage higher than the reference voltage (hereinafter also referred to as a "high voltage"). According to various embodiments of the disclosure, the electronic device 300 may receive the output power (e.g., a reference voltage and the high voltage) applied from the power supply device 390 and may charge the battery 310 in response to the applied output power.

The power supply device 390 may include a wired or wireless power supply device. According to various embodiments of the disclosure, when the power supply device 390 is a wired power supply device, the power supply device 390 may be connected to the electronic device 300 via a wired interface (e.g., the interface 177 of FIG. 1) within the electronic device 300. According to various embodiments of the disclosure, when the power supply device 390 is a wireless power supply device, the power supply device 390 may be connected to the electronic device 300 via a wireless interface (e.g., a coil).

When connected to the electronic device 300, the power supply device 390 may provide information about various levels of voltages (or currents) that may be provided from the power supply device 390 to the electronic device 300 and may supply current to the electronic device 300. The power supply device 390 may be a general power supply device or a high-speed power supply device depending on embodiments. For example, the general power supply device may supply power at a first voltage (e.g., 5 volts (V)/500 milliamperes (mA)). In addition, the high-speed power supply device may be a device that provides a faster charging speed than the charging speed supplied by the general power supply device and may provide power at a second voltage (e.g., 9 V/1.5 amperes (A)) that is higher than the first voltage (e.g., 5 V/500 mA) supplied by the general power supply device. According to an embodiment of the disclosure, when the power supply device 390 supports high-speed charging, the power supply device 390 may supply the first voltage to the electronic device 300 or may supply the second voltage, which is higher than the first voltage, to the electronic device 300. According to an embodiment of the disclosure, when the power supply device 390 supports high-speed charging, the power supply device 390 may control the power to supply, to the electronic device 300, the output power (e.g., the first voltage or the second voltage) corresponding to the charging power requested from the electronic device 300.

In various embodiments of the disclosure, the electronic device 300 may be charged (e.g., wired charging or wireless charging) in conjunction with the power supply device 390. According to an embodiment of the disclosure, the electronic device 300 may perform a charging operation based on the voltage supplied from the power supply device 390 when connected to the power supply device 390 (e.g., connected to a connector of the power supply device 390 and mounted on a charging device (e.g., a wireless charging pad)). According to an embodiment of the disclosure, the electronic device 300 may receive, through an electrical circuit, the power that is applied and transmitted from the power supply device 390 through the electrical circuit and may charge the battery 310, which is an internal battery, based on the applied power.

According to various embodiments of the disclosure, the electronic device 300 may include the battery 310, the battery management module 320 (also referred to as a "power management circuit" or a "battery control circuit"), the processor 360 (also referred to as a "control circuit"), or the like, in relation to adjusting full charge capacity information of the battery 310 and/or SOC information of the battery 310.

The battery 310 may be functionally or physically connected to the power supply device 390 through various interfaces. The battery 310 may include a positive electrode and a negative electrode. The battery 310 may include, for example, a rechargeable battery and/or a solar battery. The battery 310 may be mounted inside the electronic device 300 or formed externally. The battery 310 may be functionally, electrically, or physically connected to an electronic device (e.g., the electronic device 101 of FIG. 1) through various interfaces.

In various embodiments of the disclosure, when the power supply device 390 is connected to the electronic device 300, the battery management module 320 may recognize the power supply device 390 and may transmit the recognition of the power supply device 390 to the processor 360. The battery management module 320 is connected to the processor 360 of the electronic device 300 and may control the battery 310 under the control of the processor 360. According to various embodiments of the disclosure, the processor 360 may be interpreted as a control circuit.

According to various embodiments of the disclosure, the battery management module 320 may include a controller 325 (e.g., a micro controller unit (MCU)) for detecting state information, such as an internal defect of the battery 310 and controlling the electronic device 300 based on the detecting of the state information. According to various embodiments of the disclosure, the battery management module 320 may include a battery state measurement circuit 330 (e.g., a battery remaining capacity measurement circuit) for measuring a battery state (e.g., SOC) of the battery 310. According to various embodiments of the disclosure, the battery management module 320 may include one or more charging circuits 340 to provide a charging current to the battery 310. According to various embodiments of the disclosure, the battery management module 320 may include a boost circuit 345 and a power management integrated circuit (PMIC) 335 for charging the battery 310 and supplying power to a system load (e.g., the load 380). According to various embodiments of the disclosure, the battery management module 320 may include a coulomb counter 350 for continuously tracking the SOC and/or the state of discharge of the battery 310.

According to various embodiments of the disclosure, the coulomb counter 350 may be included within the battery state measurement circuit 330. According to an embodiment of the disclosure, when the coulomb counter 350 is included within the battery state measurement circuit 330, the battery state measurement circuit 330 may be in a form including a configuration for voltage measurement and a configuration for current measurement, such as, for example, a voltage measurement unit (not shown) and a current measurement unit (not shown). According to an embodiment of the disclosure, when the coulomb counter 350 is included within the battery state measurement circuit 330, the processor 360 may receive data from at least a portion of the voltage measurement unit (not shown) or the current measurement unit and may calculate at least a portion of the voltage or current of the battery 310 based on the received data to calculate the SOC of the battery 310. According to various embodiments of the disclosure, the amount of electric charge accumulated in the battery 310 may be calculated through the current measurement unit (not shown) of the battery state measurement circuit 330.

According to various embodiments of the disclosure, the battery management module 320 may further include a separate switch (not shown) (e.g., a field effect transistor (FET) circuit) to supply a current path of the power supply device 390 to the battery 310 or to a circuit (e.g., the load 380) of the electronic device 300 that requires power other than the battery 310.

According to various embodiments of the disclosure, the electronic device 300 may include a switch that may selectively connect the battery 310 to the battery management module 320 of the electronic device 300. The processor 360 may perform measurement, at least as part of an operation of measuring first information (e.g., the first voltage) and second information (e.g., the second voltage) of the battery 310, in a state in which the battery 310 and the battery management module 320 are opened by using the switch or in a circuit connection state to represent an effect equivalent thereto. According to an embodiment of the disclosure, the processor 360 may measure an open circuit voltage (OCV) in the state in which the connection between the battery 310 and the battery management module 320 is open or in the circuit connection state to represent the effect equivalent thereto.

The battery state measurement circuit 330 may include, for example, a fuel gauge (F/G) integrated circuit (IC). According to an embodiment of the disclosure, the battery state measurement circuit 330 may be configured to include the coulomb counter 350 therein. The battery state measurement circuit 330 may measure information of the battery 310. According to various embodiments of the disclosure, the information of the battery 310 may include remaining capacity, a voltage, a current, or temperature during charging. According to an embodiment of the disclosure, the battery state measurement circuit 330 may measure the information of the battery 310 based on a signal received through an electrical path connected to the battery 310. According to various embodiments of the disclosure, the battery state measurement circuit 330 may provide the measured information of the battery 310 to the processor 360.

The PMIC 335 may manage power of the electronic device 300. The PMIC 335 may be implemented in a wired and/or wireless charging method. In various embodiments of the disclosure, the wireless charging method may include, for example, a magnetic resonance method, a magnetic induction method, or an electromagnetic wave method. The PMIC 335 in the wireless charging method may further include additional circuits for wireless charging, such as a coil loop, a resonant circuit, or a rectifier.

The charging circuit 340 may provide a voltage applied through the boost circuit 345 or an external device (e.g., the power supply device 390) to at least one of the PMIC 335 or the battery 310.

The boost circuit 345 may be connected to the battery 310 and may boost a voltage of the connected battery 310 to provide the boosted voltage to the charging circuit 340.

The coulomb counter 350 may provide the processor 360 with information about how much current has flowed into the battery 310. According to an embodiment of the disclosure, the coulomb counter 350 may be included in the battery state measurement circuit 330. According to an embodiment of the disclosure, the coulomb counter 350 may continuously track (or monitor) the charge/discharge state (e.g., current used) of the battery 310 and may output a pulse each time a provided amount of current is used to provide the processor 360 with information about the remaining capacity of the battery 310. According to various embodiments of the disclosure, by using the battery state measurement circuit 330 and the coulomb counter 350, more accurate state information of the battery 310 (e.g., the remaining capacity of the battery 310 based on voltage and/or current) may be provided. According to an embodiment of the disclosure, an error (e.g., offset) that may accumulate due to continuous current measurement in the coulomb counter 350 may be corrected using a voltage measurement value of the battery state measurement circuit 330. For example, a voltage method and a coulomb count method may be used together to reduce an issue (e.g., offset) of the coulomb method, thereby improving accuracy.

According to various embodiments of the disclosure, the battery management module 320 may include the controller 325 (e.g., a processor) embedded therein and may use the embedded controller 325 to control the boost circuit 345, the charging circuit 340, the battery state measurement circuit 330, or the PMIC 335. In various embodiments of the disclosure, the controller 325 may or may not be included within the battery management module 320 depending on the implementation of the battery management module 320. According to an embodiment of the disclosure, when the battery management module 320 includes the controller 325, the controller 325 may replace the processor 360 and may process the control operations of the processor 360. For example, the controller 325 may be included in the battery management module 320 and implemented as a dedicated controller (e.g., an MCU and the processor 120 of FIG. 1) for processing operations related to adjusting the full charge capacity information of the battery 310.

According to various embodiments of the disclosure, the battery management module 320 may further include memory (not shown) embedded therein and may use the embedded memory (not shown) to store at least one piece of state information (e.g., first state information, second state information, or the like) obtained from an operation related to charging of the battery 310. In various embodiments of the disclosure, the memory for storing state information related to the state of the battery 310 may be implemented by general memory (e.g., the memory 130 of FIG. 1) or a dedicated memory embedded in the battery management module 320.

In various embodiments of the disclosure, the processor 360 may determine the state of the battery 310 based on information provided by the battery management module 320. The processor 360 may display a user interface for notification information related to the battery 310 on a display (e.g., the display module 160 of FIG. 1) based on a result of determining the state of the battery 310. According to various embodiments of the disclosure, the processor 360 may control the battery 310 based on the state of the battery 310. According to various embodiments of the disclosure, the processor 360 may allow a user of the electronic device 300 to confirm the user interface related to the state of the battery 310 and may control operations related to the battery 310 according to commands input from the user.

According to various embodiments of the disclosure, the processor 360 may periodically confirm the SOC information of the battery state measurement circuit 330 or the charging current and full charge interrupt of the charging circuit 340 through the battery management module 320 and may confirm a full charge state of the battery 310. According to an embodiment of the disclosure, when the battery 310 is fully charged, the processor 360 may control the battery management module 320 to supply power required for the electronic device 300 from the power supply device 390, rather than from the battery 310. According to an embodiment of the disclosure, the electronic device 300 may control power supply through a switch circuit (e.g., a FET circuit) based on an input voltage. According to an embodiment of the disclosure, the electronic device 300 may control the switch circuit via an electrical signal based on the control of the processor 360.

According to various embodiments of the disclosure, the processor 360 may obtain voltage information and/or current information about the battery 310 based at least in part on the battery state measurement circuit 330 and/or the coulomb counter 350 and may determine whether there is a leakage inside the battery 310 based on the obtained information. According to various embodiments of the disclosure, the processor 360 may include a full charge capacity information determination module 370 for determining the full charge capacity information of the battery 310.

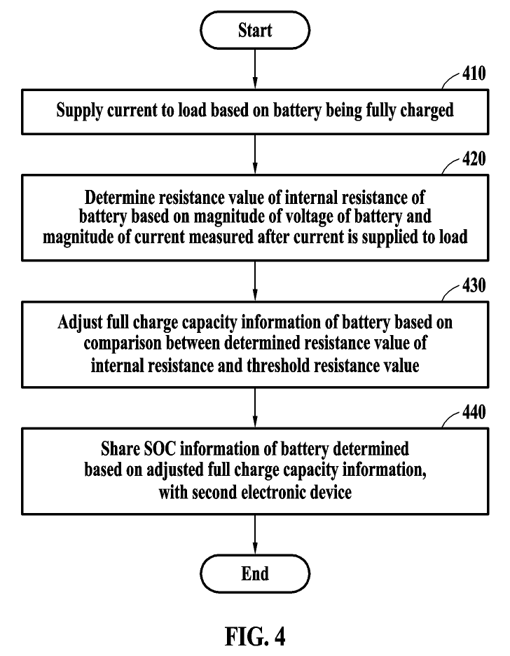

According to an embodiment of the disclosure, the processor 360 may determine the full charge capacity information of the battery 310 based on at least one of the voltage or the current of the battery 310 and/or the load 380. For example, the processor 360 may determine a resistance value of an internal resistance of the battery 310 and may adjust the full charge capacity information of the battery 310 based on the determined resistance value of the internal resistance. The operation of the processor 360 is described below with reference to FIGS. 4 to 9.

FIG. 4 is a flowchart illustrating a method performed by an electronic device according to an embodiment of the disclosure.

According to an embodiment of the disclosure, a first electronic device (e.g., the electronic device 101 of FIG. 1, the electronic device 200 of FIG. 2, and the electronic device 300 of FIG. 3) may determine full charge capacity information of a battery (e.g., the battery 189 of FIG. 1, the battery 289 of FIG. 2, and the battery 310 of FIG. 3) and may transmit SOC information based on the determined full charge capacity information to a second electronic device (e.g., the external electronic device 102 of FIG. 1 and the power supply device 390 of FIG. 3). In various embodiments of the disclosure, the first electronic device may be expressed as an "external device" (e.g., an external device of the first electronic device) with respect to the second electronic device. Similarly, the second electronic device may be expressed as an "external device" (e.g., an external device of the second electronic device) with respect to the first electronic device.

Referring to FIG. 4, in operation 410, the first electronic device may supply a current to a load based on the battery being fully charged.

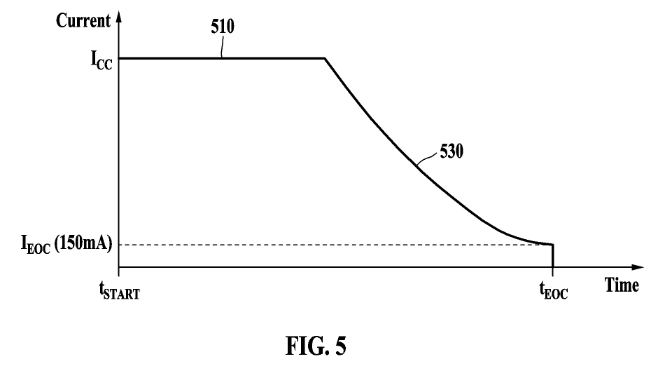

The first electronic device according to an embodiment may determine whether the battery is fully charged based on a charging current of the battery. For example, the first electronic device may determine that the battery is fully charged when a magnitude of the charging current of the battery is a current magnitude corresponding to a termination current (also expressed as an "end-of-charge (EOC) current" in the disclosure). The charging current of the battery is described in more detail below with reference to FIG. 5.

The first electronic device according to an embodiment may include the battery (e.g., the battery 189 of FIG. 1, the battery 289 of FIG. 2, and the battery 310 of FIG. 3) and a load (e.g., the load 380 of FIG. 3). The battery and the load of the first electronic device may be electrically connected to each other. The first electronic device may supply power of the battery to the load. As the power is supplied to the load, a current may flow through the load. In various embodiments of the disclosure, the supplying of the power of the battery to the load may be interpreted as substantially corresponding to supplying the current to the load using the power of the battery.

In operation 420, the first electronic device may determine (e.g., detect, recognize, sense, identify, and determine) a resistance value of an internal resistance of the battery based on a magnitude of a voltage of the battery and a magnitude of a current measured after the current is supplied to the load. The battery of the first electronic device may have the internal resistance. The internal resistance of the battery may be formed by element(s) of the battery.

According to an embodiment of the disclosure, the first electronic device may determine the resistance value of the internal resistance of the battery based on the magnitude of the voltage of the battery and the magnitude of the current applied to the load that are measured after the current is supplied to the load. A relationship (e.g., an equation) may be formed between at least two of the magnitude of the voltage of the battery (or the amount of change in the voltage), the magnitude of the current flowing through the battery (or the amount of change in the current), the magnitude of the load (e.g., resistance), the magnitude of the current flowing through the load (or the amount of change in the current), or the resistance value of the internal resistance of the battery. The first electronic device may determine the resistance value of the internal resistance of the battery by using the relationship between at least two of the magnitude of the voltage of the battery (or the amount of change in the voltage), the magnitude of the current flowing through the battery (or the amount of change in the current), the magnitude of the load (e.g., resistance), the magnitude of the current flowing through the load (or the amount of change in the current), or the resistance value of the internal resistance of the battery.

According to an embodiment of the disclosure, the first electronic device may supply the current to the load based on the magnitude of the current flowing through the load being measurable or the magnitude of the current flowing through the load being controllable. For example, the first electronic device may include a constant current source that may maintain a substantially constant amount of the current flowing through the load. For example, the first electronic device may include a current measurement circuit configured to measure the magnitude of the current flowing through the load. Since the first electronic device according to an embodiment determines the resistance value of the internal resistance of the battery based on the magnitude of the current flowing through the load, the first electronic device may supply the current to the load based on the magnitude of the current flowing through the load being measurable or the magnitude of the current flowing through the load being controllable.

In operation 430, the first electronic device may adjust (e.g., reconfigure, replace, and overwrite) full charge capacity information of the battery based on a comparison between the determined resistance value of the internal resistance and a threshold resistance value. The threshold resistance value may be stored in a storage medium included in memory of the electronic device.

The full charge capacity information of the battery may include capacity stored in the battery when the battery is fully charged. In the disclosure, the capacity stored in the battery when the battery is fully charged may also be expressed as "full charge capacity". As the battery is repeatedly charged and discharged, performance of the battery may deteriorate. Performance degradation of the battery may include a decrease in the full charge capacity of the battery and/or an increase in the resistance value of the internal resistance of the battery.

According to an embodiment of the disclosure, the first electronic device may adjust the full charge capacity information by applying a coefficient less than 1 to the full charge capacity information of the battery, based on the determined resistance value of the internal resistance being greater than or equal to the threshold resistance value. For example, the first electronic device may adjust the full charge capacity to a value obtained by multiplying the full charge capacity of the battery by the coefficient. The coefficient may have a value greater than 0 and less than 1. According to an embodiment of the disclosure, the value of the coefficient may be determined based on the threshold resistance value and/or the resistance value of the internal resistance.

According to an embodiment of the disclosure, the first electronic device may initially set the full charge capacity information of the battery to a predefined value. The first electronic device may set the full charge capacity information to the predefined value for a new battery. The first electronic device may adjust the full charge capacity information of the battery based on a full charge voltage of the battery. For example, the first electronic device may obtain full charge capacities mapped to full charge voltages. Each full charge capacity may be mapped to one full charge voltage. For example, the mapping between the full charge capacity and the full charge voltage may be determined experimentally. When the first electronic device determines to adjust the full charge capacity information of the battery, the first electronic device may adjust the full charge capacity information of the battery to have the full charge capacity mapped to the full charge voltage of the battery.

According to an embodiment of the disclosure, the first electronic device may adjust the full charge capacity information of the battery based on the number of times the determined resistance value of the internal resistance is determined to be greater than or equal to the threshold resistance value. The first electronic device may determine the resistance value of the internal resistance of the battery whenever the battery is fully charged. The first electronic device may adjust the full charge capacity information of the battery when the first electronic device determines that the resistance value of the internal resistance is greater than or equal to the threshold resistance value by a threshold number of times or more. The first electronic device according to an embodiment may adjust the full charge capacity information of the battery when the resistance value of the internal resistance is determined to be the threshold resistance value by multiple times, rather than adjusting the full charge capacity information of the battery when the resistance value of the internal resistance is determined once to be greater than or equal to the threshold resistance value, thereby preventing the full charge capacity information of the battery from being incorrectly adjusted when the resistance value of the internal resistance of the battery is incorrectly determined once.

For example, the first electronic device may store the number of times the resistance value of the internal resistance is determined to be greater than or equal to the threshold resistance value, in non-volatile memory (e.g., the non-volatile memory 134 of FIG. 1). The first electronic device may update (e.g., increase by 1) the number of times stored in the non-volatile memory when the resistance value of the internal resistance is determined to be greater than or equal to the threshold resistance value. The first electronic device may adjust the full charge capacity information of the battery based on the number of times stored in the non-volatile memory.

In operation 440, the first electronic device may share SOC information of the battery determined (e.g., detected, recognized, sensed, and identified) based on the adjusted full charge capacity information with the second electronic device.

For example, the first electronic device may transmit the SOC information to the second electronic device. For example, the second electronic device may access the first electronic device to read the SOC information of the first electronic device.

The first electronic device may determine the SOC information of the battery based on remaining capacity information of the battery and the full charge capacity information of the battery. The remaining capacity information of the battery may include the remaining capacity stored in the battery at a corresponding point in time. The first electronic device may determine the SOC information of the battery based on a ratio of the remaining capacity information to the full charge capacity information of the battery. For example, the first electronic device may determine the SOC of the battery based on a value determined by dividing the remaining capacity by the full capacity. The first electronic device may determine the SOC of the battery in percentage (%) by multiplying, by 100, the value obtained by dividing the remaining capacity by the full capacity.

According to various embodiments of the disclosure, it is mainly described that the first electronic device performs the determining of the resistance value of the internal resistance and the adjusting of the full charge capacity information in response to the battery being fully charged, but embodiments are not limited thereto. For example, the first electronic device may determine whether to perform the determining of the resistance value of the internal resistance and the adjusting of the full charge capacity information based on the battery being fully charged and a duration of a charging operation.

According to an embodiment of the disclosure, the first electronic device may determine whether to adjust the full charge capacity information of the battery based on the duration of the charging operation. For example, while the first electronic device performs the charging operation of the battery, the first electronic device may accumulate the duration of the charging operation. The duration may refer to a time length in which the magnitude of the charging current supplied to the battery is continuously maintained at a threshold current magnitude. The first electronic device may start accumulating the duration at a first point in time when the magnitude of the charging current changes from below the threshold current magnitude to exceeding the threshold current magnitude. The first electronic device may terminate the accumulating of the duration at a second point in time when the magnitude of the charging current changes from exceeding the threshold current magnitude to below the threshold current magnitude. The first electronic device may skip the determining of the resistance value of the internal resistance of the battery and the adjusting of the full charge capacity information of the battery, based on the duration of the charging operation being shorter than the threshold time length.

The first electronic device may stop supplying the charging current independently of the connection and/or disconnection between the first electronic device and a power supply device when the battery is fully charged. For example, the first electronic device may limit charging of the battery while the first electronic device is connected to the power supply device and the battery is fully charged. Subsequently, the battery may be discharged either naturally or through use of the first electronic device, and the first electronic device may recharge the battery. When the fully charged battery is fully recharged after naturally discharged while maintaining connection to the power supply device, the duration of the charging operation may be shorter than the threshold time length. Even when the SOC of the battery is above a certain level, the duration of the charging operation may be shorter than the threshold time length since the power required to fully charge the battery is below threshold power. The first electronic device may skip the determining of the resistance value of the internal resistance of the battery and the adjusting of the full charge capacity information of the battery, based on the duration of the charging operation being shorter than the threshold time length. The first electronic device according to an embodiment may prevent excessively frequent determining of the resistance value of the internal resistance of the battery and adjusting of the full charge capacity information of the battery by determining whether to adjust the full charge capacity information of the battery based on the duration of the charging operation.

FIG. 5 is a graph illustrating changes in a charging current during a charging operation of a battery, according to an embodiment of the disclosure.

Referring to FIG. 5, when charging of a battery (e.g., the battery 189 of FIG. 1, the battery 289 of FIG. 2, and the battery 310 of FIG. 3) starts, a charging current of the battery may maintain a specific current size (ICC) for a predetermined length of time. A section in which the specific current size is maintained (e.g., a straight section of the graph and a section in which a high charging current is maintained) may be expressed as a constant current (CC) section 510 of a charging operation of the battery.

When a voltage of the battery reaches near a full charge voltage, the voltage of the battery may be maintained at a substantially specific voltage (e.g., a full charge voltage) and the charging current of the battery may decrease. A section in which the voltage of the battery is maintained at the specific voltage and the charging current of the battery decreases (e.g., a downward curve section of the graph and a section in which the charging current decreases) may be expressed as a constant voltage (CV) section 530 of the charging operation of the battery.

The charging of the battery may be completed at a point in time (tEOC) in which a magnitude of the charging current of the battery reaches an EOC current magnitude (IEOC), and supplying of the charging current may be stopped. The EOC current magnitude (IEOC) may be a current magnitude specified according to the design.

According to an embodiment of the disclosure, a first electronic device (e.g., the electronic device 101 of FIG. 1, the electronic device 200 of FIG. 2, and the electronic device 300 of FIG. 3) may determine that the battery is fully charged based on the charging current of the battery. For example, the first electronic device may determine that the battery is fully charged based on the magnitude of the charging current of the battery being a threshold current magnitude (e.g., the EOC current magnitude (IEOC)).

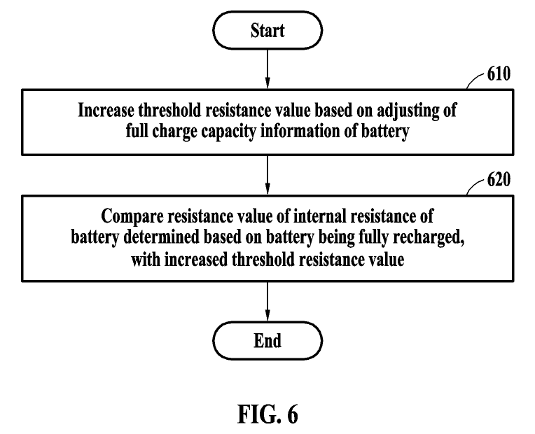

FIG. 6 is a flowchart illustrating changing a threshold resistance value by a first electronic device according to an embodiment of the disclosure.

According to an embodiment of the disclosure, a first electronic device (e.g., the electronic device 101 of FIG. 1, the electronic device 200 of FIG. 2, and the electronic device 300 of FIG. 3) may change a threshold resistance value when full charge capacity information is adjusted.

Referring to FIG. 6, in operation 610, the first electronic device may increase the threshold resistance value based on adjusting of the full charge capacity information of a battery.

As described above, according to performance degradation of the battery, a resistance value of an internal resistance of the battery may increase, and full charge capacity of the battery may decrease. The first electronic device may adjust the full charge capacity information of the battery when the resistance value of the internal resistance of the battery increases from a first resistance value to a second resistance value due to the performance degradation of the battery. The threshold resistance value may be set to a value greater than the first resistance value and less than the second resistance value. After the full charge capacity information of the battery is adjusted, the performance of the battery may degrade further. The first electronic device may increase an internal resistance value of the battery from the second resistance value to a third resistance value as the performance of the battery degrades further. The first electronic device may increase the threshold resistance value to a value greater than the second resistance value (or the existing threshold resistance value) considering that the internal resistance value of the battery may further increase as the performance of the battery degrades further.

In operation 620, the first electronic device may compare the resistance value of the internal resistance of the battery determined based on the battery being fully recharged, with the increased threshold resistance value.

After changing the full charge capacity information of the battery and the threshold resistance value, the battery may be recharged. The first electronic device may redetermine the resistance value of the internal resistance of the battery based on the battery being fully recharged. The first electronic device may compare the redetermined resistance value of the internal resistance of the battery with the increased threshold resistance value. The first electronic device may adjust the full charge capacity information of the battery based on a comparison between the redetermined resistance value of the internal resistance of the battery and the increased threshold resistance value.

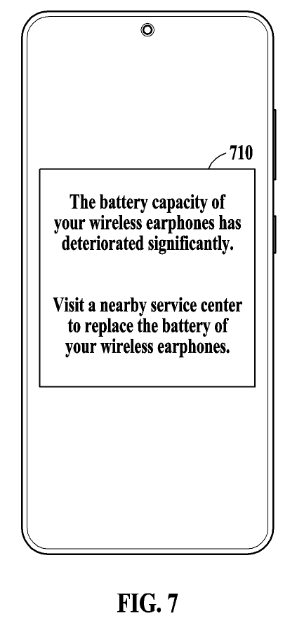

FIG. 7 is a diagram illustrating an example of displaying a screen based on obtained information by a second electronic device that has obtained the information about a battery of a first electronic device from the first electronic device, according to an embodiment of the disclosure.

According to an embodiment of the disclosure, the first electronic device (e.g., the electronic device 101 of FIG. 1, the electronic device 200 of FIG. 2, and the electronic device 300 of FIG. 3) may transmit information about the battery of the first electronic device and/or a screen display command to a second electronic device (e.g., the external electronic device 102 of FIG. 1). The information about the battery may include at least one of full charge capacity information, SOC information, or remaining capacity information. The screen display command may cause the second electronic device that has received the screen display command to display a screen based on the information about the battery.

For example, the first electronic device may transmit the SOC information of the battery to the second electronic device based on adjusting of the full charge capacity information of the battery. The second electronic device may obtain the SOC information of the battery of the first electronic device from the first electronic device based on adjusting of the full charge capacity information of the battery of the first electronic device. For example, the second electronic device may receive the SOC information of the battery from the first electronic device. For example, the second electronic device may access the first electronic device to read the SOC information of the battery of the first electronic device.

The SOC information of the battery of the first electronic device may be determined using the adjusted full charge capacity information. The second electronic device may display the screen based on the SOC information of the battery of the first electronic device.

According to an embodiment of the disclosure, based on obtaining of the information about the battery from the first electronic device, the second electronic device may display the screen based on the obtained information.

Referring to FIG. 7, for example, the first electronic device may transmit a display command on a screen 710 for recommending replacement of the battery to the second electronic device, based on the adjusted full charge capacity information. The second electronic device may display the screen 710 for recommending replacement of the battery based on obtaining, from the first electronic device, the display command on the screen 710 for recommending replacement of the battery.

According to an embodiment of the disclosure, the second electronic device may include a communication module, a display module, a memory, and a processor. The communication module of the second electronic device may establish communication with the first electronic device including the battery. The communication module of the second electronic device may be configured to be identical or similar to a communication module (e.g., the communication module 190 of FIG. 1) of the first electronic device. The second electronic device may receive the information about the battery from the first electronic device through the communication module. The display module of the second electronic device may display a screen based on the information about the battery. The memory of the second electronic device may store instructions. The processor of the second electronic device may access the memory of the second electronic device and may execute the instructions. The display module of the second electronic device, the memory of the second electronic device, and the processor of the second electronic device may respectively be configured to be identical or similar to a display module (e.g., the display module 160 of FIG. 1) of the first electronic device, memory (e.g., the memory 130 of FIG. 1) of the first electronic device, and a processor (e.g., the processor 120 of FIG. 1) of the first electronic device.

According to an embodiment of the disclosure, the first electronic device may be implemented as wireless earphones, and the second electronic device may be implemented as a portable communication device (e.g., a smartphone).

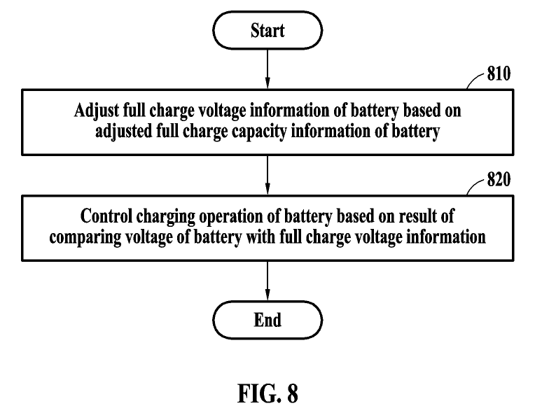

FIG. 8 is a flowchart illustrating a method of controlling a charging operation of a battery by a first electronic device according to an embodiment of the disclosure.

According to an embodiment of the disclosure, a first electronic device (e.g., the electronic device 101 of FIG. 1, the electronic device 200 of FIG. 2, and the electronic device 300 of FIG. 3) may control charging of a battery (e.g., the battery 189 of FIG. 1, the battery 289 of FIG. 2, and the battery 310 of FIG. 3) based on adjusted full charge capacity information of the battery.

Referring to FIG. 8, in operation 810, the first electronic device may adjust full charge voltage information of the battery based on the adjusted full charge capacity information of the battery.

The full charge voltage information of the battery may include a voltage magnitude of the battery measured at a point in time the battery is fully charged. In the disclosure, the voltage magnitude of the battery measured at the point in time when the battery is fully charged may also be expressed as a "full charge voltage". Due to performance degradation of the battery, a resistance value of an internal resistance of the battery may increase, full charge capacity of the battery may decrease, and the full charge voltage of the battery may decrease. The first electronic device according to an embodiment may adjust (e.g., decrease) the full charge voltage information of the battery as the full charge capacity information of the battery is adjusted (e.g., decreased). As the full charge voltage information of the battery is adjusted, the first electronic device may prevent the battery from being overcharged by not adjusting the full charge voltage of the battery even though the full charge capacity of the battery has decreased. According to an embodiment of the disclosure, the first electronic device may adjust the full charge voltage information of the battery to a value specified according to the design.

In operation 820, the first electronic device may control a charging operation of the battery based on a result of comparing a voltage of the battery with the full charge voltage information.

As described above with reference to FIG. 5, in a CC section of the charging operation of the battery, a charging current of a substantially constant magnitude may be supplied to the battery. Subsequently, when the magnitude of the voltage of the battery approaches the full charge voltage (e.g., a difference between the magnitude of the voltage of the battery and the full charge voltage is less than or equal to a threshold voltage) as the charging operation progresses, a CV section may start during the charging operation of the battery, and a magnitude of the charging current supplied to the battery may decrease.

According to an embodiment of the disclosure, the first electronic device may adjust (e.g., decrease) the full charge voltage of the full charge voltage information based on adjusting of the full charge capacity information of the battery. The first electronic device may adjust the magnitude of the charging current to be supplied to the battery, based on the adjusted full charge voltage information of the battery. According to an embodiment of the disclosure, a battery management module (e.g., the battery management module 320 of FIG. 3) of the first electronic device may determine whether to maintain (e.g., supply a charging current corresponding to the CC section) or decrease (e.g., supply a charging current corresponding to the CV section) the charging current to be supplied to the battery, based on a comparison between the voltage and the full charge voltage information of the battery.

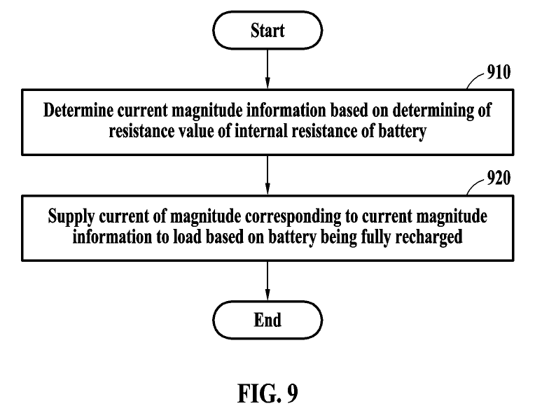

FIG. 9 is a flowchart illustrating a method of determining current magnitude information about a current supplied to a load by a first electronic device according to an embodiment of the disclosure.

According to an embodiment of the disclosure, a first electronic device (e.g., the electronic device 101 of FIG. 1, the electronic device 200 of FIG. 2, and the electronic device 300 of FIG. 3) may determine a resistance value of an internal resistance of a battery and when the battery is fully recharged, may then determine a magnitude of a current to be supplied to a load to redetermine the resistance value of the internal resistance of the battery.

Referring to FIG. 9, in operation 910, the first electronic device may determine current magnitude information based on the determining of the resistance value of the internal resistance of the battery.

Due to performance degradation of the battery, the resistance value of the internal resistance of the battery may increase. The resistance value of the internal resistance of the battery may increase from a first resistance value to a second resistance value. Even when the magnitude of the current supplied to the load is equal, a decrease in a voltage magnitude that appears in a voltage of the battery as the current is supplied to the load may be greater when the resistance value of the internal resistance is the first resistance value than when the resistance value of the internal resistance is the second resistance value. The first electronic device according to an embodiment may adjust (e.g., decrease) the magnitude of the current applied to the load to control the decrease in the voltage magnitude that appears in the voltage of the battery as the current is supplied to the load to be less than or equal to a threshold voltage magnitude.

In operation 920, the first electronic device may supply a current of a magnitude corresponding to the current magnitude information to the load based on the battery being fully recharged.

When the battery is fully recharged after determining the current magnitude information, the first electronic device may supply, to the load, the current corresponding to the current magnitude information determined for the load in order to redetermine the resistance value of the internal resistance of the battery. The first electronic device may determine the resistance value of the internal resistance of the battery based on the magnitude of the current supplied to the load and the decrease in the voltage of the battery.

Although not explicitly shown in FIG. 9, the first electronic device may compare the redetermined resistance value of the internal resistance with a threshold resistance value (or an adjusted threshold resistance value). The first electronic device may adjust full charge capacity information of the battery based on a comparison between the redetermined resistance value of the internal resistance and the threshold resistance value.

The electronic device according to various embodiments may be one of various types of electronic devices. The electronic device may include, for example, a portable communication device (e.g., a smartphone), a computer device, a portable multimedia device, a portable medical device, a camera, a wearable device, or a home appliance device. According to an embodiment of the disclosure, the electronic device is not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related components. As used herein, "A or B," "at least one of A and B," "at least one of A or B," "A, B or C," "at least one of A, B and C," and "at least one of A, B, or C," may include any one of the items listed together in the corresponding one of the phrases, or all possible combinations thereof. Terms, such as "1st" and "2nd," or "first" and "second" may be used to simply distinguish a corresponding component from other components, and do not limit the components in other aspects (e.g., importance or order). It is to be understood that if a component (e.g., a first component) is referred to, with or without the term "operatively" or "communicatively", as "coupled with," "coupled to," "connected with," or "connected to" another component (e.g., a second component), the component may be coupled with the other component directly (e.g., by wire), wirelessly, or via a third component.

As used in connection with embodiments of the disclosure, the term "module" may include a unit implemented in hardware, software, or firmware, and may interchangeably be used with other terms, for example, "logic," "logic block," "part," or "circuitry." A module may be a single integral component, or a minimum unit or part thereof, adapted to perform one or more functions. For example, according to an embodiment of the disclosure, the module may be implemented in a form of an application-specific integrated circuit (ASIC).

Various embodiments as set forth herein may be implemented as software (e.g., the program 140) including one or more instructions that are stored in a storage medium (e.g., the internal memory 136 or the external memory 138) that is readable by a machine (e.g., the electronic device 101). For example, a processor (e.g., the processor 120) of the machine (e.g., the electronic device 101) may invoke at least one of the one or more instructions stored in the storage medium, and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term "non-transitory" simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment of the disclosure, a method according to various embodiments of the disclosure may be included and provided in a computer program product. The computer program product may be traded as a product between a seller and a buyer. The computer program product may be distributed in the form of a machine-readable storage medium (e.g., compact disc read-only memory (CD-ROM)), or be distributed (e.g., downloaded or uploaded) online via an application store (e.g., PlayStore^{TM}), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to various embodiments of the disclosure, each component (e.g., a module or a program) of the above-described components may include a single entity or multiple entities, and some of the multiple entities may be separately disposed in different components. According to various embodiments of the disclosure, one or more of the above-described components or operations may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to various embodiments of the disclosure, operations performed by the module, the program, or another component may be carried out sequentially, in parallel, repeatedly, or heuristically, or one or more of the operations may be executed in a different order or omitted, or one or more other operations may be added.

The units described herein may be implemented using a hardware component, a software component and/or a combination thereof. A processing device may be implemented using one or more general-purpose or special-purpose computers, such as, for example, a processor, a controller and an arithmetic logic unit (ALU), a digital signal processor (DSP), a microcomputer, a field-programmable gate array (FPGA), a programmable logic unit (PLU), a microprocessor, or any other device capable of responding to and executing instructions in a defined manner. The processing device may run an operating system (OS) and one or more software applications that run on the OS. The processing device also may access, store, manipulate, process, and generate data in response to execution of the software. For purpose of simplicity, the description of a processing device is singular; however, one of ordinary skill in the art will appreciate that a processing device may include a plurality of processing elements and a plurality of types of processing elements. For example, the processing device may include a plurality of processors, or a single processor and a single controller. In addition, different processing configurations are possible, such as parallel processors.

The software may include a computer program, a piece of code, an instruction, or some combination thereof, to independently or uniformly instruct or configure the processing device to operate as desired. Software and data may be embodied permanently or temporarily in any type of machine, component, physical or virtual equipment, or computer storage medium or device capable of providing instructions or data to or being interpreted by the processing device. The software also may be distributed over network-coupled computer systems so that the software is stored and executed in a distributed fashion. The software and data may be stored in a non-transitory computer-readable recording medium.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments of the disclosure, or they may be of the kind well-known and available to those having skill in the computer software arts. Examples of non-transitory computer-readable media include magnetic media, such as hard disks, floppy disks, and magnetic tape; optical media, such as CD-ROM discs and digital versatile discs (DVDs); magneto-optical media, such as optical discs; and hardware devices that are specially configured to store and perform program instructions, such as read-only memory (ROM), random access memory (RAM), flash memory, and the like. Examples of program instructions include both machine code, such as one produced by a compiler, and files containing higher-level code that may be executed by the computer using an interpreter.

The above-described hardware devices may be configured to act as one or more software modules in order to perform the operations of the above-described embodiments of the disclosure, or vice versa.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method of any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a battery having an internal resistance;
a load electrically connected to the battery;
a communication circuit configured to establish communication with an external device;
memory, comprising one or more storage media, storing instructions and a threshold resistance value; and
at least one processor, comprising a processing circuit, communicatively coupled to the battery, the load, the communication circuit, and the memory,
wherein the instructions, when executed by the at least one processor individually or collectively, cause the electronic device to:
supply a current to the load based on the battery being fully charged,
determine a resistance value of the internal resistance based on a magnitude of a voltage of the battery and a magnitude of a current measured while supplying the current to the load,
adjust full charge capacity information of the battery based on a comparison between the determined resistance value of the internal resistance and the threshold resistance value, and
share state of charge (SOC) information of the battery determined based on the adjusted full charge capacity information with the external device.

2. The electronic device of claim 1, wherein the instructions, when executed by the at least one processor individually or collectively, further cause the electronic device to:
determine the SOC information of the battery based on remaining capacity information of the battery and the full charge capacity information of the battery.

3. The electronic device of claim 1, wherein the instructions, when executed by the at least one processor individually or collectively, further cause the electronic device to:
adjust the full charge capacity information of the battery by applying a coefficient less than 1 to the full charge capacity information, based on the determined resistance value of the internal resistance being greater than or equal to the threshold resistance value.

4. The electronic device of claim 1, wherein the instructions, when executed by the at least one processor individually or collectively, further cause the electronic device to:
adjust the full charge capacity information of the battery based on a number of times the determined resistance value of the internal resistance is determined to be greater than or equal to the threshold resistance value.

5. The electronic device of claim 1, wherein the instructions, when executed by the at least one processor individually or collectively, further cause the electronic device to:
increase the threshold resistance value based on the adjusting of the full charge capacity information of the battery, and
compare the resistance value of the internal resistance of the battery determined based on the battery being fully recharged, with the increased threshold resistance value.

6. The electronic device of claim 1, wherein the instructions, when executed by the at least one processor individually or collectively, further cause the electronic device to:
transmit a display command on a screen for recommending replacement of the battery to the external device, based on the adjusted full charge capacity information.

7. The electronic device of claim 1, wherein the instructions, when executed by the at least one processor individually or collectively, further cause the electronic device to:
adjust full charge voltage information of the battery based on the adjusted full charge capacity information of the battery, and
control a charging operation of the battery based on a result of comparing the voltage of the battery with the full charge voltage information.

8. The electronic device of claim 7, wherein the instructions, when executed by the at least one processor individually or collectively, further cause the electronic device to:
accumulate a duration of the charging operation while performing the charging operation of the battery, and
skip the determining of the resistance value of the internal resistance of the battery and the adjusting of the full charge capacity information of the battery, based on the duration of the charging operation being shorter than a threshold time length.

9. The electronic device of claim 1, wherein the instructions, when executed by the at least one processor individually or collectively, further cause the electronic device to:
supply a current to the load based on a magnitude of the current flowing through the load being measurable or the magnitude of the current flowing through the load being controllable.

10. The electronic device of claim 1, wherein the instructions, when executed by the at least one processor individually or collectively, further cause the electronic device to:
determine current magnitude information based on the determining of the resistance value of the internal resistance of the battery, and
supply a current of a magnitude corresponding to the current magnitude information to the load based on the battery being fully recharged.

11. An electronic device comprising:
a communication circuit configured to establish communication with an external device including a battery;
a display;
memory, comprising one or more storage media, storing instructions; and
at least one processor, comprising a processing circuit, communicatively coupled to the communication circuit, the display, and the memory,
wherein the instructions, when executed by the at least one processor individually or collectively, cause the electronic device to:
based on adjusting full charge capacity information of the battery, obtain, from the external device, state of charge (SOC) information of the battery determined using the adjusted full charge capacity information, and
display a screen based on the SOC information.

12. A method performed by an electronic device, the method comprising:
supplying a current to a load that is electrically connected to a battery, based on the battery being fully charged;
determining a resistance value of an internal resistance of the battery based on a magnitude of a voltage of the battery and a magnitude of a current measured while supplying the current to the load;
adjusting full charge capacity information of the battery based on a comparison between the determined resistance value of the internal resistance and a threshold resistance value; and
sharing state of charge (SOC) information of the battery determined based on the adjusted full charge capacity information with an external device.

13. The method of claim 12, wherein the sharing of the SOC information of the battery comprises:
determining the SOC information of the battery based on remaining capacity information of the battery and the full charge capacity information of the battery.

14. The method of claim 12, wherein the determining of the resistance value of the internal resistance of the battery comprises:
adjusting the full charge capacity information of the battery by applying a coefficient less than 1 to the full charge capacity information, based on the determined resistance value of the internal resistance being greater than or equal to the threshold resistance value.

15. The method of claim 12, further comprising:
increasing the threshold resistance value based on the adjusting of the full charge capacity information of the battery; and
comparing the resistance value of the internal resistance of the battery determined based on the battery being fully recharged, with the increased threshold resistance value.

16. The method of claim 12, further comprising:
transmitting a display command on a screen for recommending replacement of the battery to the external device, based on the adjusted full charge capacity information.

17. The method of claim 12, further comprising:
adjusting full charge voltage information of the battery based on the adjusted full charge capacity information of the battery; and
controlling a charging operation of the battery based on a result of comparing the voltage of the battery with the full charge voltage information.

18. One or more non-transitory computer-readable storage media storing one or more computer programs comprising computer-executable instructions that, when executed by one or more processors of an electronic device individually or collectively, cause the electronic device to perform operations, the operations comprising:
supplying a current to a load that is electrically connected to a battery, based on the battery being fully charged;
determining a resistance value of an internal resistance of the battery based on a magnitude of a voltage of the battery and a magnitude of a current measured while supplying the current to the load;
adjusting full charge capacity information of the battery based on a comparison between the determined resistance value of the internal resistance and a threshold resistance value; and
sharing state of charge (SOC) information of the battery determined based on the adjusted full charge capacity information with an external device.

19. The one or more non-transitory computer-readable storage media of claim 18, wherein the sharing of the SOC information of the battery comprises:
determining the SOC information of the battery based on remaining capacity information of the battery and the full charge capacity information of the battery.

20. The one or more non-transitory computer-readable storage media of claim 18, wherein the determining of the resistance value of the internal resistance of the battery comprises:
adjusting the full charge capacity information of the battery by applying a coefficient less than 1 to the full charge capacity information, based on the determined resistance value of the internal resistance being greater than or equal to the threshold resistance value.
